(19) United States
(12) Patent Application Publication
(10) Pub. No.: US 2009/0291514 A1
(43) Pub. Date: Nov. 26, 2009

(54) Process management method and process management data for semiconductor device

(75) Inventor: Yoshihiko Asai, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/453,336

(22) Filed: May 7, 2009

(30) Foreign Application Priority Data
May 22, 2008 (JP) 2008-133868

(51) Int. Cl. H01L 21/66; G06F 19/00

(52) U.S. Cl. 438/17; 702/57; 257/E21.531

(57) ABSTRACT

A process management method for managing manufacturing variability of an interconnection included in a semiconductor device is provided. The process management method includes: calculating interconnect resistance and interconnect capacitance regarding an interconnection included in the semiconductor device, under a condition that manufacturing variability of a width and a thickness of the interconnection is expressed by points on a predetermined circle of equal probability of a joint probability density function; and defining, based on the calculated interconnect resistance and interconnect capacitance, a variation range of interconnect resistance and interconnect capacitance caused by manufacturing variability. The variation range is defined two-dimensionally in a coordinate system where a first axis represents interconnect resistance and a second axis represents interconnect capacitance.

### INCORPORATION BY REFERENCE

This application is based upon and claims the benefit of priority from Japanese patent application No. 2008-133868, filed on May 22, 2008, the disclosure of which is incorporated herein in its entirety by reference.

### BACKGROUND OF THE INVENTION

1. Field of the Invention

The present invention relates to a technique of managing manufacturing variability of an interconnection and a device included in a semiconductor device.

2. Description of Related Art

In a manufacturing process of a semiconductor device, an interconnect structure may not be manufactured as expected. That is, physical parameters such as a width and a thickness of an interconnection, a thickness of an interlayer insulating film and the like may vary from their desired design values. Such manufacturing variability of the interconnect structure affects delay in a circuit. Thus, even if a designed circuit passes delay verification on a computer, an actual product may malfunction since the manufacturing variability occurs. Therefore, it is desirable to perform the delay verification in consideration of the manufacturing variability.

Japanese Laid-Open Patent Application JP-2003-108622 discloses a method of interconnect modeling in consideration of the manufacturing variability. According to the method, an arbitrary region in a semiconductor device is selected and an interconnect area ratio in the selected region is calculated. Then, the region and the interconnect area ratio are determined to model a cross-sectional shape of a target interconnection located at the center of the region.

Meanwhile, to consider the manufacturing variability during delay verification means that a condition to be met in the delay verification becomes stricter. As the condition becomes stricter, the delay verification is more likely to result in fail and thus the number of circuit design modification times increases. This causes increase in a design time required for the circuit design.

Japanese Laid-Open Patent Application JP-2006-209702 discloses a technique that can suppress increase in a circuit design time while considering the manufacturing variability. According to the technique, unrealistic patterns of the manufacturing variability are excluded from consideration. For example, let us consider a case where a width and a thickness of an interconnection can vary from respective design values in a range from −3σ to +3σ (σ: standard deviation). In this case, a probability that both the width and thickness “simultaneously” vary to the maximum extent is extremely low from a statistical point of view. If such extreme situations are taken into consideration, it is necessary to support those extreme situations, which causes increase in the number of circuit design modification times. Therefore, according to the technique, such the extreme situations are excluded from the consideration (this scheme is hereinafter referred to as “statistical relaxation”). More specifically, the statistical relaxation is applied to calculation of corner conditions under which an interconnect delay becomes maximum or minimum. Then, interconnect resistance and interconnect capacitance under the corner conditions are provided as a library. This library is referred to in LPE (Layout Parameter Extraction). Consequently, it is possible to perform delay verification in consideration of the manufacturing variability while excluding the extreme situations. In other words, it is possible to perform high-accuracy delay verification while preventing unnecessary increase in the circuit design time.

The inventor of the present application has recognized the following points. With speeding up and increasing miniaturization of a semiconductor device, management of manufacturing variability of an interconnection becomes more and more important. To that end, it is necessary in a development stage to previously estimate manufacturing variability of interconnect characteristics such as interconnect resistance and interconnect capacitance based on process specification and an interconnect model. This enables checking measured values of the interconnect characteristics of an actually manufactured circuit. In order to improve precision of the checking of the measured values, it is preferable to estimate the manufacturing variability of the interconnect characteristics in view of “realistic trend” as much as possible. It is therefore desirable to provide in the development stage an indicator of the realistic trend of the manufacturing variability of the interconnect characteristics.

### SUMMARY

In one embodiment of the present invention, a process management method for managing manufacturing variability of an interconnection included in a semiconductor device is provided. The process management method includes: (A) calculating interconnect resistance and interconnect capacitance regarding an interconnection included in the semiconductor device, under a condition that manufacturing variability of a width and a thickness of the interconnection is expressed by points on a predetermined circle of equal probability of a JPDF (Joint Probability Density Function); and (B) defining, based on the calculated interconnect resistance and interconnect capacitance, a variation range of interconnect resistance and interconnect capacitance caused by manufacturing variability. The variation range is defined two-dimensionally in a coordinate system where a first axis represents interconnect resistance and a second axis represents interconnect capacitance. The variation range thus defined is a useful “indicator” on managing the manufacturing variability of the interconnection.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a schematic diagram showing a model of a target interconnection;

FIG. 2 shows a probability distribution of manufacturing variability;

FIG. 3 is a conceptual diagram for explaining statistical relaxation;

FIG. 4 is a graph showing variation of interconnect resistance and interconnect capacitance in a case of inverse relationship;

FIG. 5 shows a distribution of measured values of interconnect RC;

FIG. 6 is a conceptual diagram showing an interconnect management range according to an embodiment of the present invention;

FIG. 7 is a conceptual diagram showing an interconnect management range according to an embodiment of the present invention;

FIG. 8 shows an example of the interconnect management range in the present embodiment;

FIG. 9 shows another example of the interconnect management range in the present embodiment;

FIG. 10 shows another example of the interconnect management range in the present embodiment;

FIG. 11 shows another example of the interconnect management range in the present embodiment;

FIG. 12 shows another example of the interconnect management range in the present embodiment;

FIG. 13 shows another example of the interconnect management range in the present embodiment;

FIG. 14 is a flow chart showing a method of calculating the interconnect management range according to the present embodiment;

FIG. 15 is a conceptual diagram for explaining Step S10;

FIG. 16 is a conceptual diagram for explaining Step S10;

FIG. 17 is a conceptual diagram for explaining Step S20;

FIG. 18 is a conceptual diagram for explaining Step S20;

FIG. 19 is a conceptual diagram for explaining Step S20;

FIG. 20 is a conceptual diagram for explaining Step S30;

FIG. 21 is a conceptual diagram for explaining Step S30;

FIG. 22 is a conceptual diagram for explaining Step S40;

FIG. 23 is a block diagram showing a configuration of a process management system according to the present embodiment;

FIG. 24 is a flow chart showing development and manufacturing method for a semiconductor device according to the present embodiment; and

FIG. 25 is a graph showing an actual example of measured values of the interconnect RC and the interconnect management range.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

In the present embodiment, a technique of managing manufacturing variability of an interconnection included in a semiconductor device is provided.

1. Overview

With speeding up and increasing miniaturization of a semiconductor device, management of manufacturing variability of an interconnection becomes more and more important. To that end, it is necessary in a development stage to previously estimate manufacturing variability of interconnect characteristics such as interconnect resistance and interconnect capacitance based on process specification and an interconnect model. The interconnect characteristics such as interconnect resistance and interconnect capacitance may hereinafter be referred to as “interconnect RC”. By previously estimating the interconnect RC, it is possible to check measured values of the interconnect RC of an actually manufactured circuit. If the measured value greatly deviates from the estimated value, there may be something wrong with the process or the interconnect model and it is possible to improve the process or the interconnect model as appropriate. As remarked above, the management of manufacturing variability of the interconnection is effective also in verifying validity of the process and the interconnect model.

In order to improve precision of the checking of the measured values, it is preferable to estimate the manufacturing variability of the interconnect RC in view of “realistic trend” as much as possible. One object of the present invention is to provide in the development stage an “indicator” of the realistic trend of the manufacturing variability of the interconnect RC.

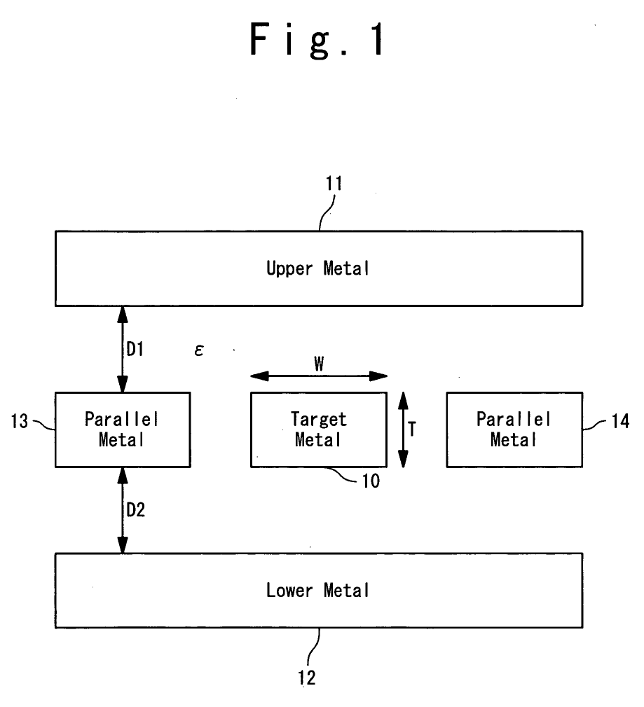

FIG. 1 shows an interconnect model (interconnect structure pattern). In FIG. 1, target for the calculation of the interconnect RC is a target interconnection (target metal) 10. An upper interconnection (upper metal) 11 is formed over the target interconnection 10 through an interlayer insulating film. Similarly, a lower interconnection (lower metal) 12 is formed under the target interconnection 10 through an interlayer insulating film. Also, parallel interconnections (parallel metals) 13 and 14 are formed in the same interconnection layer as the target interconnection 10.

The interconnect RC of the target interconnection 10 depends on a width W and a thickness T of the target interconnection 10, physical parameters of the surrounding interlayer insulating film and so on. The physical parameters of the surrounding interlayer insulating film include a film thickness D1 (i.e., a distance to the upper interconnection 11), a film thickness D2 (i.e., a distance to the lower interconnection 12), relative permittivity ε and the like. In an actually manufactured semiconductor device, these parameters (W, T, D1, D2, ε) contributing to the interconnect RC usually deviate from the respective design values. In other words, the manufacturing variability occurs in the parameters contributing to the interconnect RC. For example, the width W and the thickness T of the target interconnection 10 are expressed by the following equation (1).

W=W0+δW

T=T0+δT Equation (1):

Here, W0 and T0 represent design values (center condition) of the width W and the thickness T, respectively. Also, δW and δT represent manufacturing variability from the design values of the width W and the thickness T, respectively. The manufacturing variability δW and δT each has a certain probability distribution.

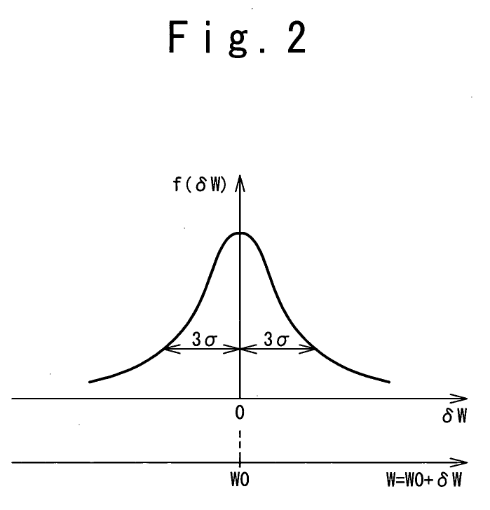

For example, FIG. 2 shows a probability distribution of the manufacturing variability 6W of the width W. In FIG. 2, the abscissa axis represents the manufacturing variability δW, the vertical axis represents probability density, and a probability density function is expressed by f(δW). The probability distribution shown in FIG. 2 is obtained based on actual measurement or the process specification. Data indicating the probability distribution is hereinafter referred to as “variation distribution data”. Typically, the probability distribution of the manufacturing variability is expressed by a normal distribution (i.e., f(δW)=N(0, σ)). In this case, the variation distribution data may just indicate a standard deviation σ of the normal distribution. The standard deviation σ is determined based on actual measurement or the process specification. The same applies to the manufacturing variability δT of the interconnect thickness T.

By using the interconnect model shown in FIG. 1 and the variation distribution data shown in FIG. 2, it is possible to estimate the interconnect RC in consideration of the manufacturing variability. Parameters most contributing to the interconnect RC are the interconnect width W and the interconnect thickness T. Therefore, the manufacturing variability δW and δT are mainly considered in the present embodiment. First, let us consider a statistically-sufficient range, typically a range of −3σ to +3σ (see FIG. 2), with regard to each of the manufacturing variability δW and δT. Further, we consider realistic trend of δW and δT as much as possible, in order to estimate the manufacturing variability of the interconnect RC in view of realistic trend as much as possible. To that end, the scheme of “statistical relaxation” is employed also in the present embodiment.

The statistical relaxation will be described below in detail. First of all, note that there is no correlation between δW and δT. In other words, an event of “variation in the interconnect width W” and an event of “variation in the interconnect thickness T” are independent of each other. This is obvious from a fact that a process determining the interconnect thickness T is different from a process determining the interconnect width W in a typical manufacturing process for the semiconductor device. The interconnect thickness T is determined by a film deposition process and a CMP (Chemical Mechanical Polishing) process. On the other hand, the interconnect width W is determined by a lithography process. As mentioned above, δW and δT are independent variables that vary independently of each other. This means that a probability that both δW and δT simultaneously take the maximum values is extremely low. For example, a case where δW=+3σ and δT=+3σ is not realistic. We can exclude such extreme situations from the consideration and just need to consider events that occur with equal to or more than a predetermined probability. This is the statistical relaxation.

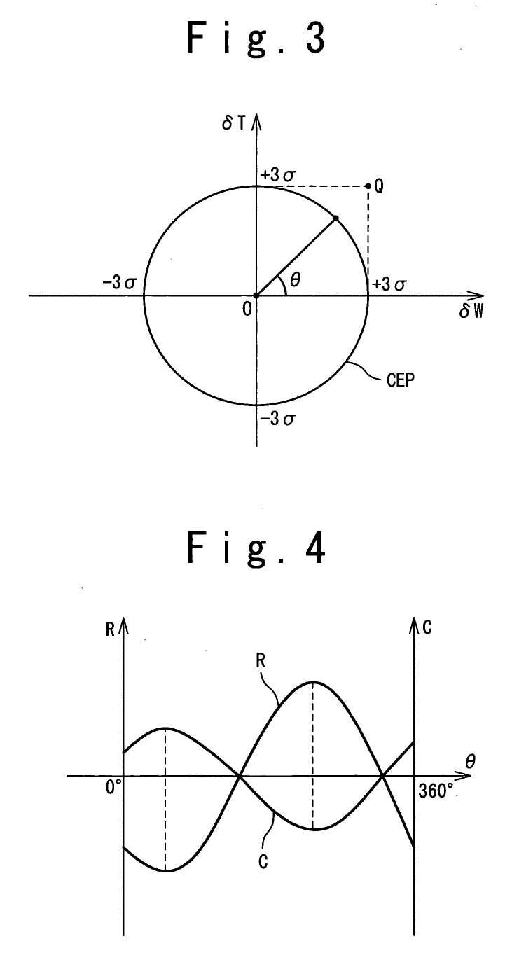

The statistical relaxation in the present embodiment will be described in more detail with reference to FIG. 3. In FIG. 3, two orthogonal axes represent the two independent variables δW and δT, respectively. Also, the origin O represents the center condition (W0 (δW=0), T0 (δT=0)). In the foregoing FIG. 2, the one-dimensional probability density function (f(δW)) is defined. In the plane shown in FIG. 3, it is possible to define a “joint probability density function (JPDF)” of δW and δT. The JPDF is sometimes called a “joint distribution function (JDF)”. By the JPDF, probability is defined at each point (δW, δT) in the plane shown in FIG. 3.

Let us consider a case where a probability distribution of each of δW and δT is a normal distribution as shown in FIG. 2. Also, we consider a statistically-sufficient range of −3σ to +3σ with regard to each of δW and δT. Since δW and δT are variables independent of each other, a probability p1 (δW=+3σ, δT=0), a probability p2 (δW=0, δT=+3σ), a probability p3 (δW=−3σ, δT=0) and a probability p4 (δW=0, δT=−3σ) are equal to each other. There are many other points that occur with the same probability as the probabilities p1 to p4. A set of the points occurring with the equal probability form a curve CEP shown in FIG. 3, and the curve CEP is hereinafter referred to as a “circle of equal probability CEP”. The probabilities that the manufacturing variability corresponding to the points on the circle of equal probability CEP occur are all the same. It should be noted that a point on the circle of equal probability CEP can be defined by a radius 3σ and an angle θ as shown in FIG. 3.

Meanwhile, since δW and δT are variables independent of each other, a probability that both δW and δT “simultaneously” take the maximum values is extremely low. For example, manufacturing variability indicated by a point Q (δW=+3σ, δT=+3σ) in FIG. 3 is not realistic. Therefore, in the present embodiment, such extreme situations are excluded from the consideration and only events occurring with equal to or more than a predetermined probability are considered. It is preferable to use the above-described circle of equal probability CEP as the predetermined probability. That is to say, only points within the predetermined circle of equal probability CEP whose radius is 3σ are considered according to the present embodiment. Consequently, extreme situations such as the point Q are excluded from the consideration and thus the statistical relaxation is achieved.

According to the present embodiment, as described above, the statistical relaxation is considered with regard to the manufacturing variability δW and δT of the interconnection. Consequently, it is possible to estimate the manufacturing variability of the interconnect RC in view of realistic trend. In order to estimate a variation range of the interconnect resistance, the interconnect resistance is calculated under a condition that δW and δT are expressed by the points on the predetermined circle of equal probability CEP of the JPDF. Similarly, in order to estimate a variation range of the interconnect capacitance, the interconnect capacitance is calculated under the condition that δW and δT are expressed by the points on the predetermined circle of equal probability CEP of the JPDF.

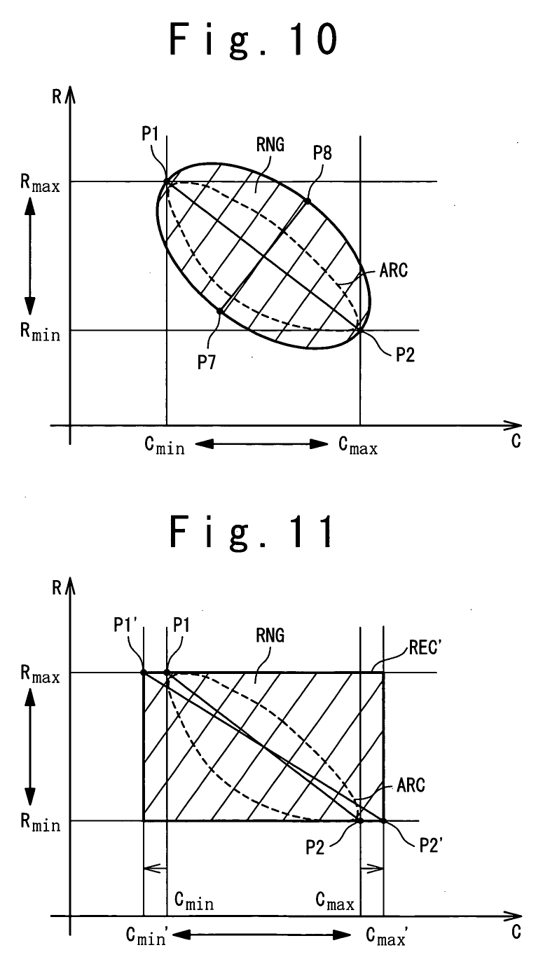

FIG. 4 shows one example of variations of the interconnect resistance R and the interconnect capacitance C calculated under the above-mentioned condition, which is described in FIGS. 10A and 10B of Japanese Laid-Open Patent Application JP-2006-209702. In FIG. 4, the abscissa axis represents the angle θ (refer to FIG. 3) and the vertical axis represents the interconnect resistance R or the interconnect capacitance C. The interconnect resistance R and the interconnect capacitance C are calculated with respect to various angles θ under the condition that δW and δT are expressed by the points on the circle of equal probability CEP of the JPDF. In this manner, the variation range of the interconnect resistance R and the variation range of the interconnect capacitance C can be calculated.

According to the technique described in Japanese Laid-Open Patent Application JP-2006-209702, a relationship between the interconnect resistance R and the interconnect capacitance C is assumed to be “absolute inverse proportion” for simplicity. This assumption is based on concept that the interconnect resistance R is a decreasing function of an interconnect cross-sectional area while the interconnect capacitance C is an increasing function of the interconnect cross-sectional area. In this case, as shown in FIG. 4, the interconnect capacitance C takes the maximum value when the interconnect resistance R takes the minimum value. On the other hand, the interconnect capacitance C takes the minimum value when the interconnect resistance R takes the maximum value. That is, the interconnect resistance R and the interconnect capacitance C vary in a simple inverse proportional manner.

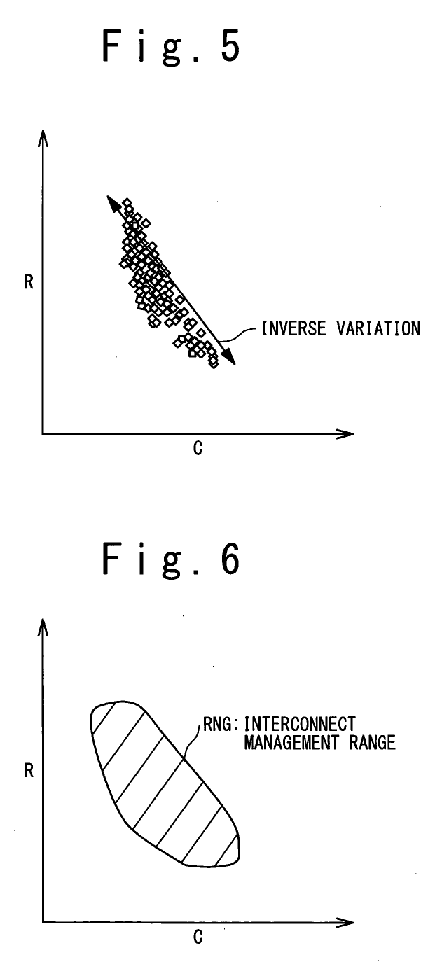

However, the inventor of the present application has focused on the following points. FIG. 5 shows a distribution of measured values of the interconnect RC with regard to a certain interconnection. The vertical axis represents measured values of the interconnect resistance R and the abscissa axis represents measured values of the interconnect capacitance C. The distribution of the measured values was obtained by using a plurality of wafers actually fabricated. As shown in FIG. 5, the interconnect resistance R and the interconnect capacitance C has a distribution caused by the manufacturing variability and a relationship between them is roughly an inverse proportion. However, the interconnect capacitance C can be various with respect to the same interconnect resistance R. Similarly, the interconnect resistance R can be various with respect to the same interconnect capacitance C. That is to say, the simple inverse variation as shown in FIG. 4 is unable to fully represent the actual distribution of the interconnect RC. In other words, the one-dimensional inverse proportional curve in the case of Japanese Laid-Open Patent Application JP-2006-209702 does not sufficiently reflect the realistic trend of the interconnect RC. In order to manage the manufacturing variability of the interconnect RC, not the simple one-dimensional curve but a “two-dimensional range” having an area should be used.

The present embodiment is based on the recognition described above. That is, a variation range of the interconnect RC caused by the manufacturing variability is defined beforehand for the purpose of the management of the manufacturing variability of the interconnection. The variation range is so determined as to reflect the realistic trend of the manufacturing variability as much as possible. To that end, the statistical relaxation is considered and moreover the variation range is defined by a “two-dimensional range” having an area. The variation range thus defined is hereinafter referred to as an “interconnect management range RNG”.

FIG. 6 schematically shows the interconnect management range RNG according to the present embodiment. A coordinate system where the first axis represents the interconnect resistance R and the second axis orthogonal to the first axis represents the interconnect capacitance C is shown in FIG. 6. This coordinate system is hereinafter referred to as an “RC coordinate system”. According to the present embodiment, the interconnect management range RNG is defined two-dimensionally in the RC coordinate system. Moreover, the statistical relaxation is considered on determining the interconnect management range RNG. More specifically, the interconnect resistance R and the interconnect capacitance C are calculated under the condition that the manufacturing variability δW and δT of the interconnection are expressed by the points on the predetermined circle of equal probability CEP of the JPDF. Then, based on the calculated interconnect resistance R and interconnect capacitance C, the interconnect management range RNG in the RC coordinate system is defined.

The interconnect management range RNG (RC variation range) thus defined well reflects the realistic trend of the manufacturing variability. Therefore, the interconnect management range RNG can be a useful “indicator” on managing the manufacturing variability of the interconnection. For example, it is possible to check whether or not a measured value of the interconnect RC of an actually manufactured circuit is included in the interconnect management range RNG. In other words, it is possible to utilize the interconnect management range RNG as a corner condition of the interconnect RC. The interconnect management range RNG according to the present embodiment will be described below in more detail.

2. Interconnect Management Range RNG

According to the present embodiment, the scheme of statistical relaxation is used on determining the interconnect management range RNG. More specifically, the interconnect resistance R and the interconnect capacitance C of the target interconnection 10 are calculated under the condition that δW and δT are expressed by the points on the predetermined circle of equal probability CEP of the JPDF (refer to FIG. 3). The interconnect resistance R per unit length of the target interconnection 10 is calculated by the following equation (2).

R=ρ/(W×T)=ρ/{(W0+δW)×(T0+δT)} Equation (2):

Here, the parameter ρ is electrical resistivity (unit: Ωm) and depends on interconnection material, temperature, dose amount and so on. Here, copper or aluminum is used as the interconnection material, and the temperature is 25 degrees centigrade. As expressed by the equation (2), the interconnect resistance R is obtained by dividing the electrical resistivity ρ by the interconnect cross-sectional area (W×T).

The interconnect capacitance C of the target interconnection 10 is calculated by utilizing TCAD (Technology CAD). At this time, the interconnection model such as shown in FIG. 1 is used and the physical parameters (D1, D2, ε) of the surrounding interlayer insulating film are set to the center condition.

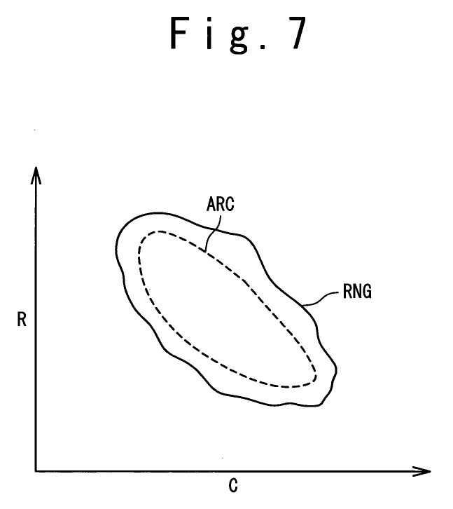

FIG. 7 illustrates a locus ARC of variation of the interconnect resistance R and the interconnect capacitance C that is calculated by the above-described method and condition. A coordinate system in FIG. 7 is the above-mentioned RC coordinate system. The locus ARC represents how the interconnect RC varies when δW and δT are changed on the circle of equal probability CEP (see FIG. 3), namely, when the angle θ is changed. As shown in FIG. 7, the locus ARC of the variation has a lens shape or an elliptical shape in the RC coordinate system. The interconnect capacitance C does not necessarily take the maximum value when the interconnect resistance R takes the minimum value. Similarly, the interconnect capacitance C does not necessarily take the minimum value when the interconnect resistance R takes the maximum value. This also indicates that the assumption that the interconnect resistance R and the interconnect capacitance C vary in a simple inverse proportional manner is not preferable.

As shown in FIG. 7, the interconnect management range RNG according to the present embodiment is so defined as to include the locus ARC of the interconnect RC calculated under the condition of the statistical relaxation. In other words, the interconnect management range RNG is defined by a two-dimensional range including the locus ARC. Such the interconnect management range RNG is a useful indicator that well reflects the realistic trend of the manufacturing variability. Whereas, in order to reduce unnecessary margin outside of the locus ARC, it is preferable to suppress a size of the interconnect management range RNG to some extent. Furthermore, it is desirable for use in the management of interconnection that the interconnect management range RNG has a shape defined by a finite number of points. For example, a “polygonal shape” is a shape defined by a finite number of points.

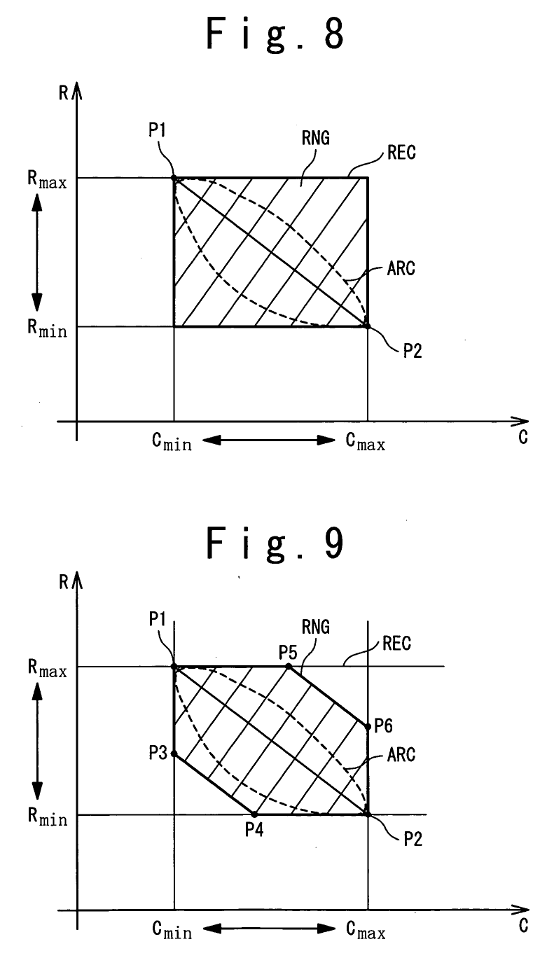

FIG. 8 shows one example of the interconnect management range RNG having a polygonal shape. On the above-described locus ARC, the interconnect resistance R varies in a range from the minimum value Rmin to the maximum value Rmax and the interconnect capacitance C varies in a range from the minimum value Cmin to the maximum value Cmax. As shown in FIG. 8, a point (Cmin, Rmax) in the RC coordinate system is a first point P1, and a point (Cmax, Rmin) in the RC coordinate system is a second point P2. A rectangular shape REC having these two points P1 and P2 as diagonal points can be defined in the RC coordinate system. The rectangular shape REC obviously includes the locus ARC of variation of the interconnect RC. Moreover, since this rectangular shape REC is tangent to the locus ARC, the rectangular shape REC is the smallest one among rectangular shapes including the locus ARC. Therefore, this rectangular shape REC can be used as the interconnect management range RNG. In this case, the interconnect management range RNG can be defined by two diagonal points P1 and P2. The two diagonal points P1 and P2 are used as management parameters defining the interconnect management range RNG and are stored in a memory device.

The interconnect management range RNG shown in FIG. 8 is the largest one among polygonal shapes included in the rectangular shape REC. In order to reduce unnecessary margin outside of the locus ARC, the interconnect management range RNG may be narrowed from the rectangular shape REC. Even in that case, it is desirable that the interconnect management range RNG includes the locus ARC. In other words, a polygonal shape including the locus ARC and included in the rectangular shape REC is preferable. FIG. 9 shows one preferable example of the interconnect management range RNG.

In the example shown in FIG. 9, a “hexagonal shape” including the locus ARC and included in the rectangular shape REC is used as the interconnect management range RNG. The hexagonal shape is defined by six points P1 to P6. The diagonal points P1 and P2 among them are the same as the above-described two points P1 and P2 that define the rectangular shape REC. The point P3 is located on a straight line of C=Cmin, the point P4 is located on a straight line of R=Rmin, and a line connecting between the points P3 and P4 exists outside of the locus ARC. Similarly, the point P5 is located on a straight line of R=Rmax, the point P6 is located on a straight line of C=Cmax, and a line connecting between the points P5 and P6 exists outside of the locus ARC. Therefore, the interconnect management range RNG having the hexagonal shape defined by the six points P1 to P6 includes the locus ARC. Thus, the six points P1 to P6 are used as management parameters defining the interconnect management range RNG and are stored in a memory device.

In the example shown in FIG. 9, the interconnect management range RNG is narrowed from the rectangular shape REC to the hexagonal shape. As described above, this hexagonal shape also has the two points P1 and P2 defining the rectangular shape REC as diagonal points. That is, the interconnect management range RNG is narrowed from the rectangular shape to the hexagonal shape with the two points P1 and P2 maintained. Since the interconnect management range RNG in the present example is smaller than the rectangular shape REC, the margin outside of the locus ARC becomes smaller than that in the case of FIG. 8, which is preferable.

A shape that can be defined by a finite number of points is not limited to the “polygonal shape” as shown in FIG. 8 and FIG. 9. For example, an elliptical shape also can be defined by a finite number of points. FIG. 10 shows one example of the interconnect management range RNG having an elliptical shape. The elliptical shape shown in FIG. 10 has the above-mentioned two points P1 and P2 as points on the long axis and other two points P7 and P8 as points on the short axis. The points P7 and P8 of the short axis are determined such that the elliptical shape includes the locus ARC. In this manner, the interconnect management range RNG having the elliptical shape can be defined by the four points P1, P2, P7 and P8. Therefore, the four points P1, P2, P7 and P8 are used as management parameters defining the interconnect management range RNG and are stored in the memory device.

In the example shown in FIG. 10, the interconnect management range RNG is deformed from the rectangular shape REC into the elliptical shape. As described above, the elliptical shape has the two points P1 and P2 defining the rectangular shape REC as the points on the long axis. That is, the interconnect management range RNG is deformed from the rectangular shape REC to the elliptical shape with the two points P1 and P2 maintained. Since the locus ARC has a lens shape or an elliptical shape, the interconnect management range RNG having the elliptical shape is preferable in terms of reduction of the unnecessary margin.

It should be noted that the interconnect management range RNG has the first point P1 and the second point P2 on the outermost, in any case shown in FIG. 8 to FIG. 10. It is possible by using these two points P1 and P2 to easily determine the interconnect management range RNG including the locus ARC and having a moderate size.

In the examples shown in FIG. 8 to FIG. 10, the manufacturing variability of only the interconnect width W and interconnect thickness T of the target interconnection 10 are taken into consideration. In addition to that, it is also possible to take manufacturing variability of the physical parameters (D1, D2, ε) of the surrounding interlayer insulating film into consideration. The manufacturing variability of the physical parameters (D1, D2, ε) affects the interconnect capacitance C of the target interconnection 10. Therefore, each point may be corrected in consideration of the influence on the interconnect capacitance C such that the interconnect management range RNG expands slightly along the second axis representing the interconnect capacitance C.

More specifically, a “correction parameter” that indicates the influence of the manufacturing variability of the physical parameters (D1, D2, ε) of the interlayer insulating film on the interconnect capacitance C is given. Typically, the correction parameter is given by a correction magnification. The interconnect capacitance C at each point is corrected by using the correction magnification. At this time, a correcting direction (increase, decrease) of the interconnect capacitance C at each point is determined such that the interconnect management range RNG expands along the second axis representing the interconnect capacitance C. For example, the minimum value Cmin is corrected to be a smaller value Cmin′ (post-correction minimum value), and the maximum value Cmax is corrected to be a larger value Cmax′ (post-correction maximum value). Note here that the interconnect resistance R at each point is not corrected.

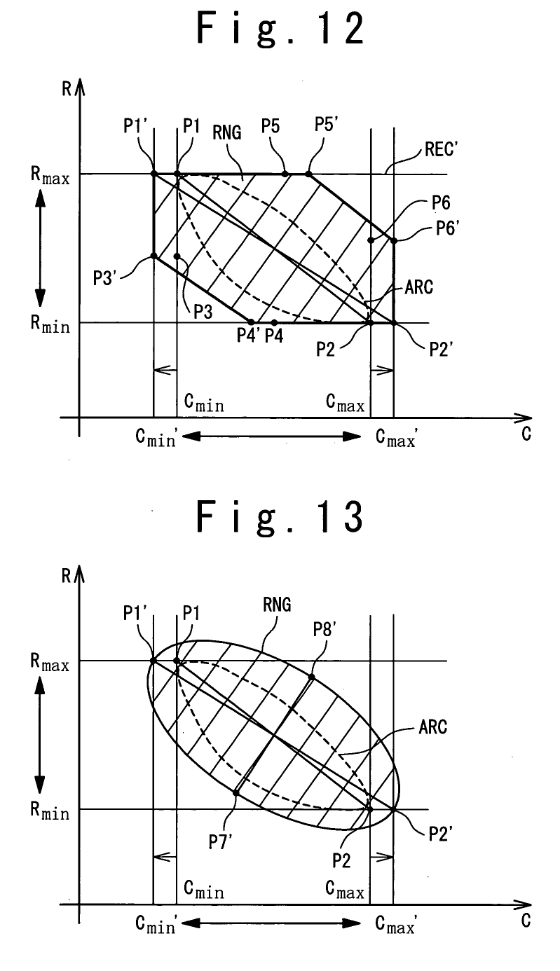

FIG. 11 shows one example of the interconnect management range RNG obtained by the correction processing. As shown in FIG. 11, a point (Cmin′, Rmax) in the RC coordinate system is a first correction point P1′. The first correction point P1′ is obtained by using the correction parameter to correct the first point P1 to be smaller in the interconnect capacitance C. Also, a point (Cmax′, Rmin) in the RC coordinate system is a second correction point P2′. The second correction point P2′ is obtained by using the correction parameter to correct the second point P2 to be larger in the interconnect capacitance C. A rectangular shape REC′ having these two correction points P1′ and P2′ as diagonal points can be defined in the RC coordinate system. In the present example, this rectangular shape REC′ is used as the interconnect management range RNG. In this case, the two diagonal points P1′ and P2′ that define the rectangular shape REC′ are used as management parameters defining the interconnect management range RNG and are stored in a memory device. The interconnect management range RNG according to the present example corresponds to a range obtained by expanding the rectangular-shaped interconnect management range RNG shown in FIG. 8 along the interconnect capacitance direction.

FIG. 12 shows another example of the interconnect management range RNG. The interconnect management range RNG according to the present example can be obtained by expanding the hexagonal-shaped interconnect management range RNG shown in FIG. 9 along the interconnect capacitance direction. More specifically, the hexagonal shape in the present example is defined by six points P1′, P2′, P3′, P4′, P5′ and P6′. The diagonal points P1′ and P2′ among them are the same as the above-described correction points P1′ and P2′ that define the rectangular shape REC′. The other points P3′, P4′, P5′ and P6′ can also be obtained by correcting the respective points P3, P4, P5 and P6 shown in FIG. 9 in a similar manner by using the correction parameter. In the present example, the six points P1′, P2′, P3′, P4′, P5′ and P6′ are used as management parameters defining the interconnect management range RNG and are stored in a memory device. It should be noted that the hexagonal shape shown in FIG. 12 is one example of polygonal shapes included in the rectangular shape REC′. The example shown in the foregoing FIG. 11 is the largest among the polygonal shapes included in the rectangular shape REC′. The margin outside of the locus ARC becomes smaller in the case of FIG. 12, which is preferable.

FIG. 13 shows an example of the interconnect management range RNG having an elliptical shape. The elliptical shape shown in FIG. 13 has the above-mentioned two correction points P1′ and P2′ as points on the long axis and other two points P7′ and P8′ as points on the short axis. The points P7′ and P8′ of the short axis are determined such that the elliptical shape includes the pre-correction interconnect management range RNG. In this manner, the interconnect management range RNG having the elliptical shape can be defined by the four points P1′, P2′, P7′ and P8′. Therefore, the four points P1′, P2′, P7′ and P8′ are used as management parameters defining the interconnect management range RNG and are stored in the memory device.

It should be noted that the interconnect management range RNG has the first correction point P1′ and the second correction point P2′ on the outermost, in any case shown in FIG. 11 to FIG. 13. It is possible by using these two correction points P1′ and P2′ to reflect the influence of the manufacturing variability of the physical parameters (D1, D2, ε) of the interlayer insulating film and to easily determine the interconnect management range RNG including having a moderate size.

3. Example of Calculating Interconnect Management Range RNG

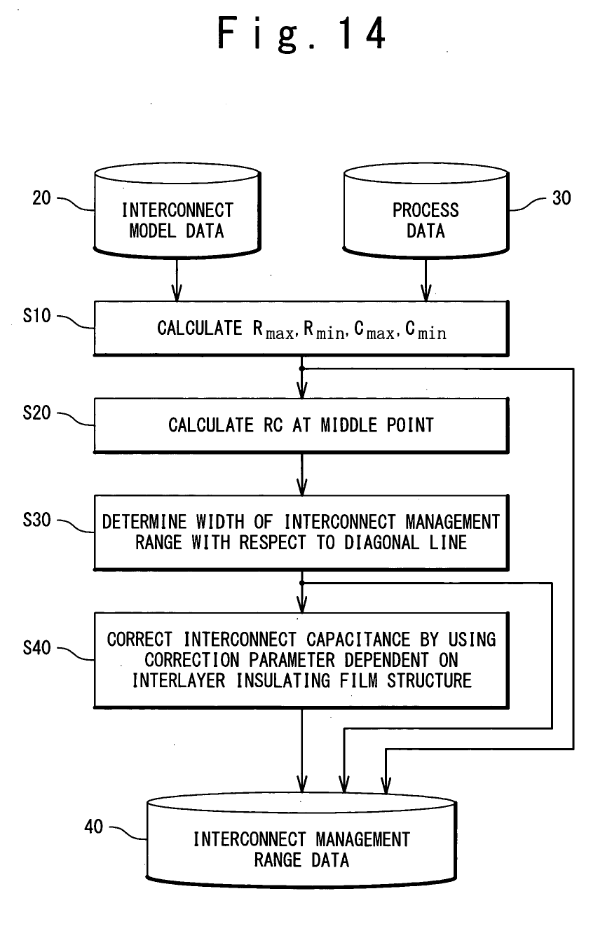

Next, an example of a method of calculating the interconnect management range RNG according to the present embodiment will be described below. FIG. 14 is a flow chart showing a method of calculating the interconnect management range RNG according to the present embodiment.

An interconnect model data 20 and a process data 30 are used in the calculation of the interconnect management range RNG. The interconnect model data 20 provides the interconnect model as shown in FIG. 14. The process data 30 provides the design value and variation distribution data of each parameter of the interconnect structure. The variation distribution data indicates information on the probability distribution of the manufacturing variability as shown in FIG. 2. Typically, the probability distribution of the manufacturing variability is expressed by a normal distribution, and the variation distribution data provides the standard deviation σ of each of δW, δT, D1, D2 and ε.

(Step S10)

First, the maximum value Rmax and the minimum value Rmin of the interconnect resistance R, the maximum value Cmax and the minimum value Cmin of the interconnect capacitance C are calculated by using the interconnect model data 20 and the process data 30. At this time, the condition of the statistical relaxation is considered. That is to say, Rmax, Rmin, Cmax and Cmin are calculated under the condition that δW and δT are expressed by the points on the predetermined circle of equal probability CEP of the JPDF (refer to FIG. 3). One preferable calculation method is as follows.

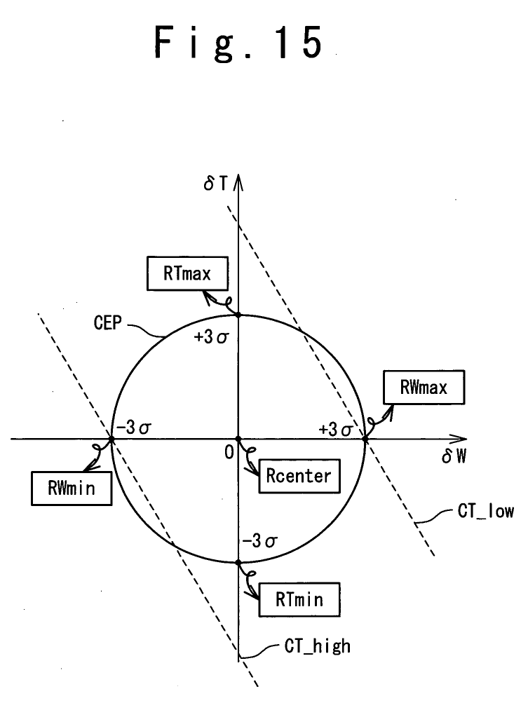

As an example, a method of calculating the maximum value Rmax and the minimum value Rmin of the interconnect resistance R will be explained below. FIG. 15 shows the circle of equal probability CEP of the JPDF of δW and δT. First, an interconnect resistance Rcenter corresponding to the origin O (W0 (δW=0), T0 (δT=0)) is calculated. Also, interconnect resistances RWmax, RWmin, RTmax and RTmin respectively corresponding to four points (δW, δT)=(+3σ, 0), (−3σ, 0) , (0, +3σ) , (0, −3σ) on the circle of equal probability CEP are calculated. Each interconnect resistance R is calculated by using the above-mentioned equation (2).

In the case of (δW, δT)=(+3σ, 0) and (0, +3σ), the interconnect cross-sectional area is larger than that in the case of the center condition, and thus the interconnect resistances RWmax and RTmax are smaller than Rcenter. On the other hand, in the case of (δW, δT)=(−3σ, 0) and (0, −3σ), the interconnect cross-sectional area is smaller than that in the case of the center condition, and thus the interconnect resistances RWmin and RTmin are larger than Rcenter. A ratio of a difference between RWmax and Rcenter to a difference between RTmax and Rcenter is αRmin, and a ratio of a difference between RWmin and Rcenter to a difference between RTmin and Rcenter is αRmax. In this case, the ratios αRmin and αRmax are expressed by the following equation (3).

αRmin=(Rcenter−RWmax)/(Rcenter−RTmax)

αRmax=(Rcenter−RWmin)/(Rcenter−RTmin) Equation (3):

Here, let us consider in FIG. 15 a line consisting of points corresponding to the same interconnect resistance R. Such a line is hereinafter referred to as a “resistance contour line”. A resistance contour line in a case where the interconnect resistance R is smaller than Rcenter is expressed by CT_low. On the other hand, a resistance contour line in a case where the interconnect resistance R is larger than Rcenter is expressed by CT_high. When the resistance contour line CT_low is approximated by a straight line, its slope is given by “−αRmin”. Similarly, when the resistance contour line CT_high is approximated by a straight line, its slope is given by “−αRmax”.

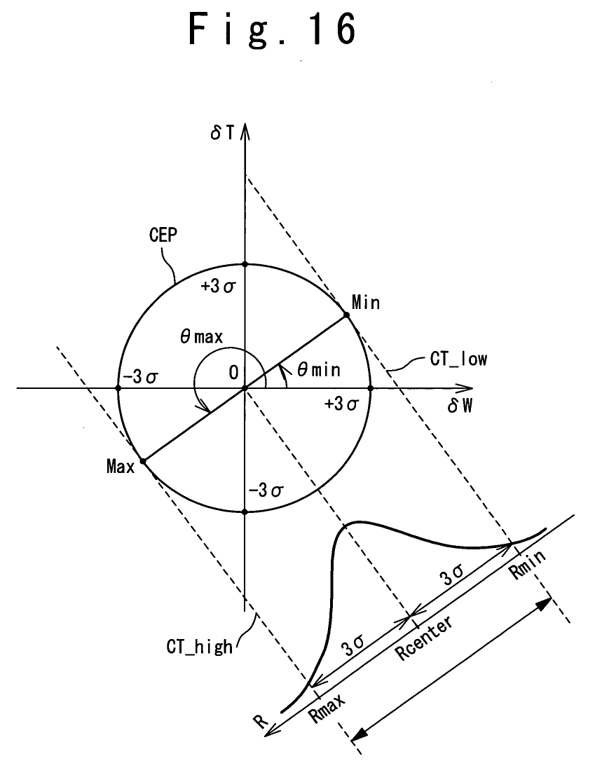

Next, as shown in FIG. 16, a contact point Min between the resistance contour line CT_low and the circle of equal probability CEP is calculated. The contact point Min is a point on the circle of equal probability CEP when the interconnect resistance R takes the minimum value Rmin. The angle in this case is θmin. Similarly, a contact point Max between the resistance contour line CT_high and the circle of equal probability CEP is calculated. The contact point Max is a point on the circle of equal probability CEP when the interconnect resistance R takes the maximum value Rmax. The angle in this case is θmax. The angles θmin and θmax are expressed by the following equation (4).

θmin=tan⁻¹(1/αRmin)

θmax=tan⁻¹(1/αRmax) Equation (4):

Since the angles θmin and θmax are calculated, the corresponding minimum value Rmin and maximum value Rmax of the interconnect resistance R can be calculated. The same applies to calculation of the minimum value Cmin and the maximum value Cmax of the interconnect capacitance C. Note here that the interconnect capacitance C is calculated by a TCAD simulation using the interconnect model. In the TCAD simulation, the physical parameters (D1, D2, ε) of the surrounding interlayer insulating film are set to the center condition.

In this manner, Rmax, Rmin, Cmax and Cmin are calculated. As a result, the first point P1 (Cmin, Rmax) and the second point P2 (Cmax, Rmin) in the RC coordinate system are determined. If the rectangular shape as shown in FIG. 8 is used as the interconnect management range RNG, the rectangular shape can be defined by these two points P1 and P2. Therefore, data indicating the two points P1 and P2 is created as an interconnect management range data 40.

(Step S20)

Next, middle angles between the angles θmin and θmax calculated with respect to the interconnect resistance R are calculated. The middle angles include two angles θmid1 and θmid2 expressed by the following equation (5).

θmid1=(θmax−θmin)/2+θmin

θmid2=(θmax−θmin)/2+θmax Equation (5):

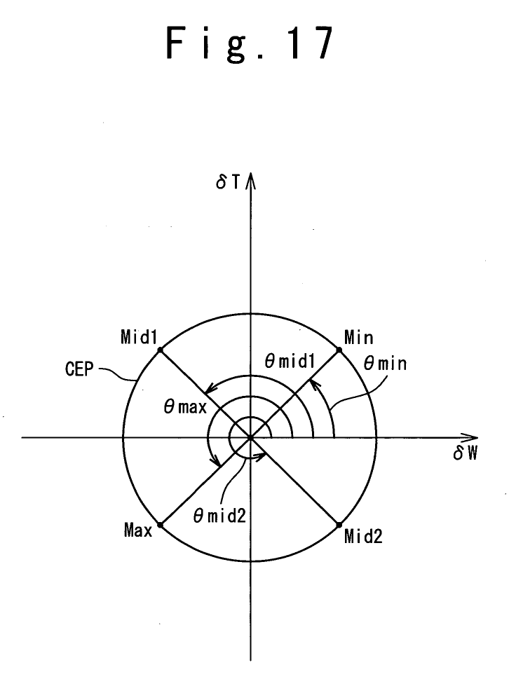

FIG. 17 shows the middle angles θmid1, θmid2 and corresponding two middle points Mid1 and Mid2 on the circle of equal probability CEP. As shown in FIG. 17, the middle point Mid1 is a middle point on an arc from the point Min toward the point Max on the circle of equal probability CEP. On the other hand, the middle point Mid2 is a middle point on an arc from the point Max toward the point Min on the circle of equal probability CEP.

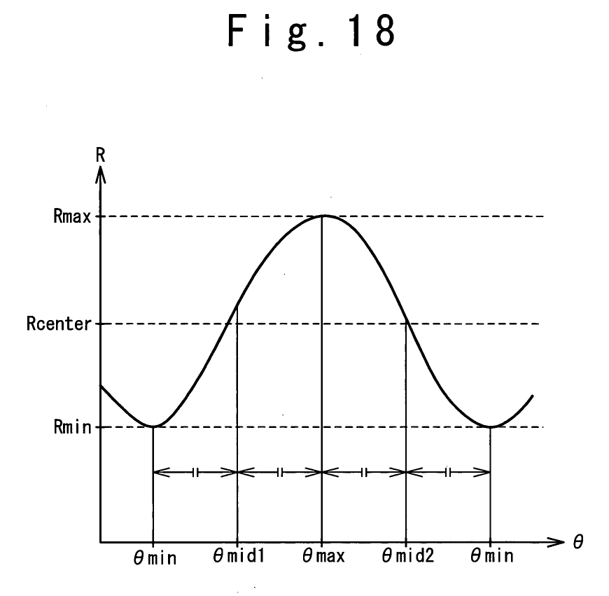

FIG. 18 shows variation in the interconnect resistance R depending on the angle θ. The abscissa axis represents the angle θ and the vertical axis represents the interconnect resistance R. As shown in FIG. 18, the variation in the interconnect resistance R has approximately a sine curve shape. When the angle θ is θmax, the interconnect resistance R becomes the maximum value Rmax. On the other hand, when the angle θ is θmin, the interconnect resistance R becomes the minimum value Rmin. The angles θmid1 and θmid2 are middle angles between the angles θmin and θmax calculated with respect to the interconnect resistance R.

Next, the middle angle θmid1 is used to calculate the interconnect resistance R and the interconnect capacitance C when δW and δT are given by the middle point Mid1. Similarly, the middle angle θmid2 is used to calculate the interconnect resistance R and the interconnect capacitance C when δW and δT are given by the middle point Mid2. Here, the interconnect resistance R is calculated by using the above-mentioned equation (2) while the interconnect capacitance C is calculated by the TCAD simulation.

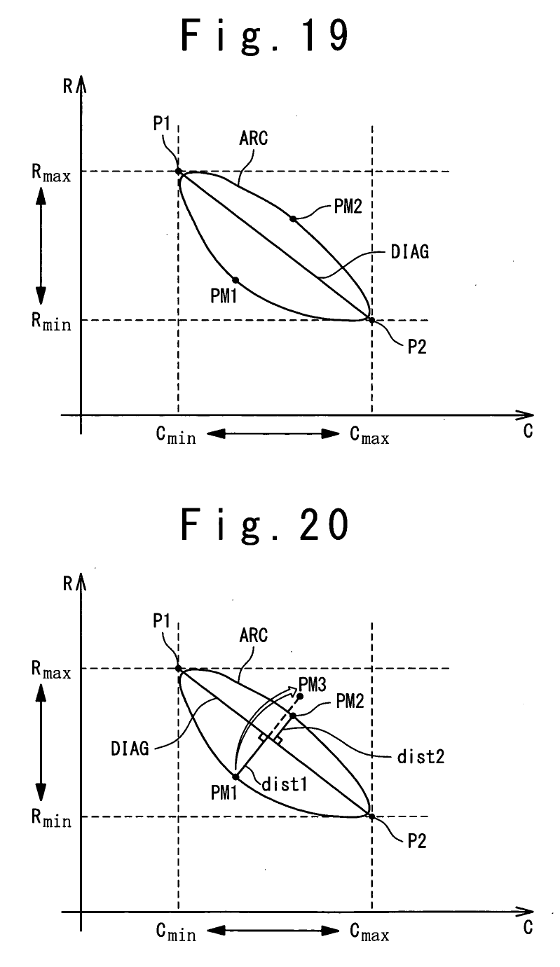

FIG. 19 shows the RC coordinate system and the locus ARC. As mentioned above, the locus ARC represents the variation in the interconnect RC corresponding to the change in the angle θ. In the RC coordinate system, a point defined by the interconnect resistance R and the interconnect capacitance C corresponding to the middle angle θmid1 is PM1. Also, in the RC coordinate system, a point defined by the interconnect resistance R and the interconnect capacitance C corresponding to the middle angle θmid2 is PM2. Naturally, these points PM1 and PM2 are located on the locus ARC.

As shown in FIG. 19, the locus ARC has an elliptical shape (or a lens shape). When a diagonal line DIAG connecting between the point P1 (Cmin, Rmax) and the point P2 (Cmax, Rmin) is considered, the locus ARC is swelling on both sides of the diagonal line DIAG. The point P1 (Cmin, Rmax) and the point P2 (Cmax, Rmin) on the diagonal line DIAG are located near points on the long axis of the locus ARC. Whereas, the points PM1 and PM2 corresponding to the middle angles are located near points where the swelling of the locus ARC with respect to the diagonal line DIAG becomes the maximum. That is to say, the points PM1 and PM2 corresponding to the middle angles give an “indication” of points on the short axis of the locus ARC.

(Step S30)

In the present embodiment, the interconnect management range RNG is so determined as to include the locus ARC. As shown in FIG. 19, the locus ARC has an elliptical shape and is swelling on both sides of the diagonal line DIAG connecting the point P1 and the point P2. Therefore, the interconnect management range RNG also is so determined as to swell on both sides of the diagonal line DIAG. In Step S30, a width of the interconnect management range RNG with respect to the diagonal line DIAG required for including the locus ARC is determined. For that purpose, the above-described points PM1 and PM2 are useful.

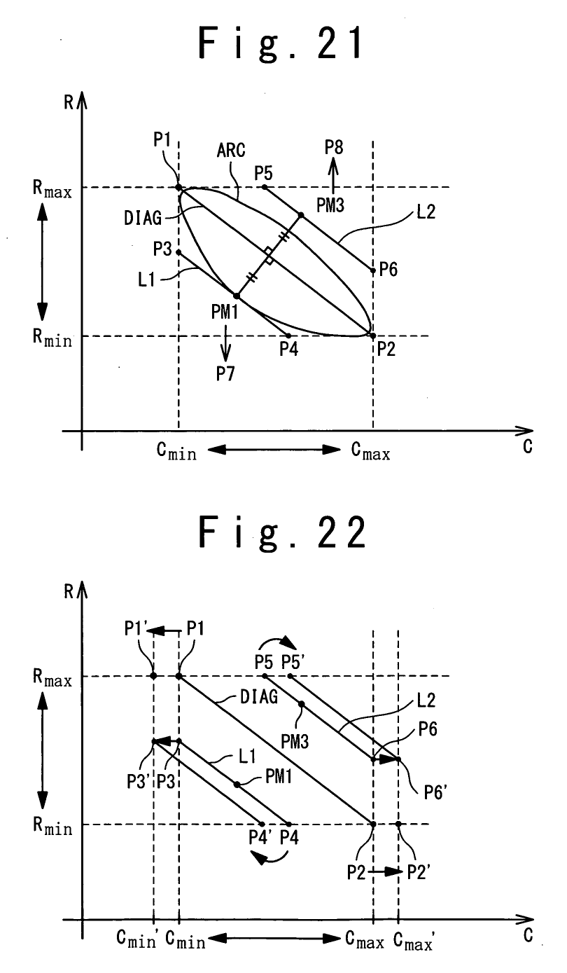

FIG. 20 shows the locus ARC and the points PM1 and PM2 in the RC coordinate system. First, a distance dist1 between the point PM1 and the diagonal line DIAG is calculated. Also, a distance dist2 between the point PM2 and the diagonal line DIAG is calculated. Subsequently, a comparison is made between the distances dist1 and dist2, and one of the points PM1 and PM2 that has larger distance to the diagonal line DIAG is selected as a first representative point. In the case of the example shown in FIG. 20, dist1 is larger than dist2, and thus the point PM1 is selected as the first representative point.

Next, a point PM3 that is symmetrically-located with respect to the first representative point PM1 across the diagonal line DIAG is calculated as a second representative point. The first representative point PM1 and the second representative point PM3 are located on both sides of the diagonal line DIAG, and respective distances to the diagonal line DIAG are of the same value (dist1). The distance (dist1) is used as the width of the interconnect management range RNG with respect to the diagonal line DIAG. This width is enough for the interconnect management range RNG to include the locus ARC.

Next, as shown in FIG. 21, a line L1 that is parallel to the diagonal line DIAG and passes through the first representative point PM1 and a line L2 that is parallel to the diagonal line DIAG and passes through the second representative point PM3 are considered. In the example shown in FIG. 21, the line L1 is closer to the origin of the RC coordinate system, and the line L2 is farther away from the origin of the RC coordinate system. In this case, an intersection between the line L1 and the line C=Cmin is calculated as the point P3, and an intersection between the line L1 and the line R=Rmin is calculated as the point P4. Also, an intersection between the line L2 and the line R=Rmax is calculated as the point P5, and an intersection between the line L2 and the line C=Cmax is calculated as the point P6.

In this manner, the points P1 to P6 are determined. As shown in FIG. 21, a hexagonal shape defined by the points P1 to P6 includes the locus ARC. Therefore, as shown in the foregoing FIG. 9, the hexagonal shape defined by the points P1 to P6 can be used as the interconnect management range RNG. In this case, data indicating the six points P1 to P6 is created as an interconnect management range data 40.

Also, as shown in the foregoing FIG. 10, the interconnect management range RNG having an elliptical shape may be used. In this case, the points P1 and P2 are used as the points on the long axis, and the above-described first representative point PM1 and second representative point PM3 are respectively used as the points (P7, P8) on the short axis. Data indicating the four points P1, P2, P7 (PM1) and P8 (PM3) is created as an interconnect management range data 40.

(Step S40)

In the above-described calculations, the manufacturing variability of the interconnect width W and interconnect thickness T of the target interconnection 10 are taken into consideration. In addition to that, it is also possible to take manufacturing variability of the physical parameters (D1, D2, ε) of the surrounding interlayer insulating film into consideration. The manufacturing variability of the physical parameters (D1, D2, ε) affects the interconnect capacitance C of the target interconnection 10. Therefore, in Step S40, the interconnect capacitance C at each point is corrected in consideration the interlayer insulating film structure. It should be noted that the interconnect resistance R at each point is not corrected.

FIG. 22 conceptually illustrates the correction processing in Step S40. As shown in FIG. 22, the points P1, P3 and P4 are corrected to be smaller in the interconnect capacitance C, and thereby the correction points P1′, P3′ and P4′ are obtained. For example, the interconnect capacitance Cmin (minimum value) at the points P1 and P3 is corrected to be a smaller value Cmin′ (post-correction minimum value). On the other hand, the points P2, P5 and P6 are corrected to be larger in the interconnect capacitance C, and thereby the correction points P2′, P5′ and P6′ are obtained. For example, the interconnect capacitance Cmax (maximum value) at the points P2 and P6 is corrected to be a larger value Cmax′ (post-correction maximum value).

In the correction processing, correction parameters (correction coefficients) βmin and βmax that depend on the interlayer insulating film structure are used. The correction parameter βmin is smaller than 1, and the post-correction interconnect capacitances at the correction points P1′, P3′ and P4′ can be calculated by multiplying the interconnect capacitances at the points P1, P3 and P4 by the correction parameter βmin, respectively. On the other hand, the correction parameter βmax is larger than 1, and the post-correction interconnect capacitances at the correction points P2′, P5′ and P6′ can be calculated by multiplying the interconnect capacitances at the points P2, P5 and P6 by the correction parameter βmax, respectively. For example, the post-correction minimum value Cmin′ and the post-correction maximum value Cmax′ are expressed by the following equation (6).

Cmin′=βmin×Cmin

Cmax′=βmax×Cmax Equation (6):

The correction parameters βmin and βmax are determined beforehand based on the manufacturing variability of the physical parameters (D1, D2, ε) of the interlayer insulating film. For example, the correction parameter βmin is determined as follows. The interconnect capacitance C becomes smaller as the relative permittivity ε becomes lower and as the film thickness D1, D2 becomes larger. Therefore, an interconnect capacitance Clow in a case where the film thickness D1, D2 is set to the maximum value (+3σ) within a predetermined variation range (−3σ to +3σ) is first calculated. Then, a ratio of the interconnect capacitance Clow to the interconnect capacitance Ccenter at the center condition is calculated as a first ratio. Meanwhile, with regard to the relative permittivity ε, a ratio of the minimum value (−3σ) within a predetermined variation range (−3σ to +3σ) to a center value is calculated as a second ratio. Then, a combination of the calculated first ratio and second ratio is used as the correction parameter βmin. In the case of the correction parameter βmax, the variation in the physical parameters is set to the opposite.

If the interconnect management range RNG shown in the foregoing FIG. 11 is used, data indicating the correction points P1′ and P2′ is created as an interconnect management range data 40. If the interconnect management range RNG shown in the foregoing FIG. 12 is used, data indicating the six correction points P1′, P2′, P3′, P4′, P5′ and P6′ is created as an interconnect management range data 40.

In this manner, the interconnect management range RNG is calculated and determined, and the interconnect management range data 40 indicating the interconnect management range RNG is created. For example, the interconnect management range data 40 indicates the points (P1, P2 and the like) which are necessary for defining the shape (polygonal, elliptical and the like) of the interconnect management range RNG. By utilizing the interconnect management range data 40, it is possible to manage the manufacturing variability of the interconnection included in the semiconductor device. It can be said that the interconnect management range data 40 is a “process management data” useful for the management of the manufacturing variability of the interconnection.

4. Process Management

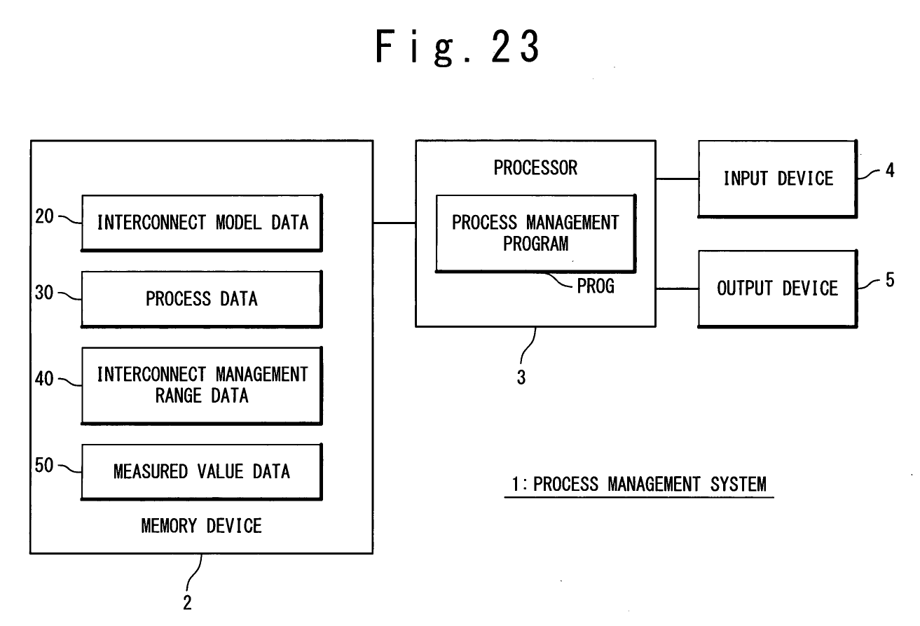

FIG. 23 is a block diagram showing a configuration of a process management system 1 according to the present embodiment. The process management system 1 is achieved by a computer and is provided with a memory device 2, a processor 3, an input device 4 and an output device 5. The memory device 2 includes a RAM and an HDD. The processor 3 includes a CPU. The input device 4 includes a key board and a mouse. The output device 5 includes a display and a printer.

The processor 3 executes a process management program PROG. The process management program PROG is software program executed by a computer. Typically, the process management program PROG is recorded on a computer-readable recording medium and read out by the processor 3. The process management according to the present embodiment is achieved by the processor 3 executing the process management program PROG.

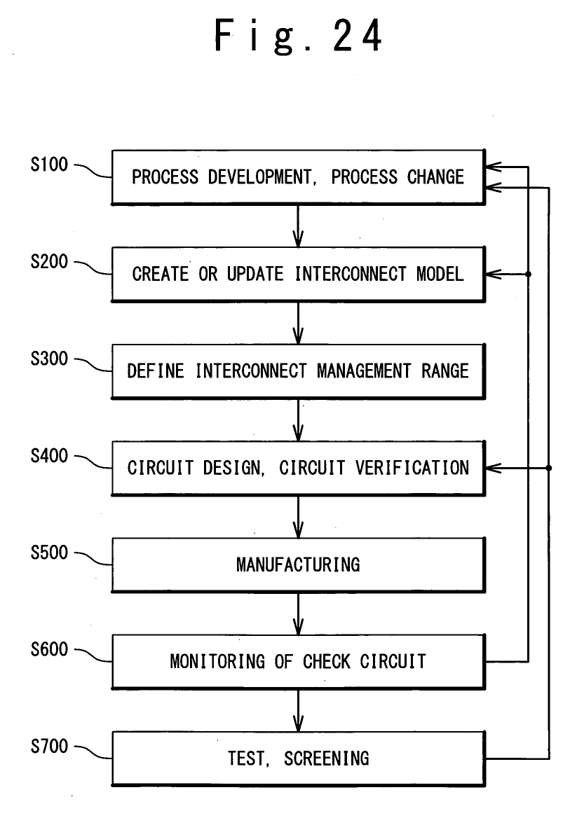

FIG. 24 is a flow chart showing development and manufacturing method for a semiconductor device according to the present embodiment. The process management according to the present embodiment will be described below with reference to FIG. 24.

(Step S100)

First, process development is performed. At this time, the process data 30 is created based on the process specification and stored in the memory device 2.

(Step S200)

Next, an interconnect model is created based on the process specification. The interconnect model is such as shown in FIG. 1. Alternatively, an interconnect model as described in Japanese Laid-Open Patent Application JP-2003-108622 may be created. The interconnect model data 20 indicating the interconnect model is created and stored in the memory device 2.

(Step S300)

Next, the process management system 1 shown in FIG. 23 defines the interconnect management range RNG. Specifically, the processor 3 executes the process management program PROG. The process management system 1 uses the interconnect model data 20 and the process data 30 stored in the memory device 2 to calculate the interconnect management range RNG in accordance with the above-described method (refer to FIG. 14: Steps S10 to S40). As a result, the interconnect management range data 40 (process management data) indicating the obtained interconnect management range RNG is created. The interconnect management range data 40 is stored in the memory device 2. The interconnect management range data 40 may be recorded on a computer-readable recording medium.

(Step S400)

Next, circuit design and circuit verification for the semiconductor device are performed. The circuit design and circuit verification are performed by a commonly-known method by the use of a computer. In the circuit verification, delay verification and timing verification are performed with respect to the designed circuit. In the delay verification and the timing verification, the interconnect management range RNG according to the present embodiment may be used as the corner condition.

(Step S500)

Next, the designed semiconductor device is actually manufactured.

(Step S600)

Next, monitoring of a check circuit or a TEG (Test Element Group) formed in the manufactured semiconductor device is performed. More specifically, the interconnect resistance R and the interconnect capacitance C of a real interconnection included in the check circuit or the TEG are actually measured. The measured values of the interconnect resistance R and the interconnect capacitance C are stored as a measured value data 50 in the memory device 2.

The process management system 1 uses the interconnect management range data 40 and the measured value data 50 to make a comparison between the interconnect management range RNG and the measured values of the interconnect RC. At this time, the measured values of the interconnect RC is compared with the interconnect management range RNG in the RC coordinate system. It is thus possible to check whether or not the measured values of the interconnect RC are included in the interconnect management range RNG. That is, the interconnect management range RNG is used as the corner condition of the interconnect RC. It should be noted that if the interconnect management range RNG has a polygonal shape or an elliptical shape that can be defined by a finite number of points, the checking procedure becomes easy, which is preferable.

Also, the process management system 1 may use the output device 5 to display the interconnect management range RNG and the measured values of the interconnect RC in the RC coordinate system. Referring to the display, a user can make a comparison between the interconnect management range RNG and the measured values of the interconnect RC. That is, a user can check whether or not the measured values of the interconnect RC are included in the interconnect management range RNG.

It is possible to feed-back a result of the above-mentioned comparison to the process and/or the interconnect model. For example, in a case where the measured values of the interconnect RC deviate from the interconnect management range RNG, there may be something wrong with the process or the interconnect model. Therefore, the process or the interconnect model is changed and improved as appropriate. Also, in a case where the interconnect management range RNG is too large as compared with a distribution of the measured values, the process data 30 may be changed such that the interconnect management range RNG becomes narrower. As described above, the interconnect management range RNG is also useful for verifying validity of the process and the interconnect model.

If the process is to be modified, the procedure returns back to the above-mentioned Step S100. If the interconnect model is to be modified, the procedure returns back to the above-mentioned Step S200. If the interconnect model data 20 and/or the process data 30 is modified (updated) due to the feed-back, the interconnect management range RNG also is modified (updated). Thereafter, the new interconnect management range RNG is used.

(Step S700)

In Step S700, test of the manufactured semiconductor device is performed. If a result of the test is FAIL, the procedure returns back to the above-mentioned Step S400 and the circuit design is performed again. Alternatively, the procedure returns back o the above-mentioned Step S100 and the process is modified. It is also possible to screen the manufactured semiconductor devices based on the result of the comparison in Step S600. For example, in the case where the measured values of the interconnect RC deviate from the interconnect management range RNG, the manufactured semiconductor devices are judged to be defective products. In this manner, the interconnect management range RNG can be used for management of production line.

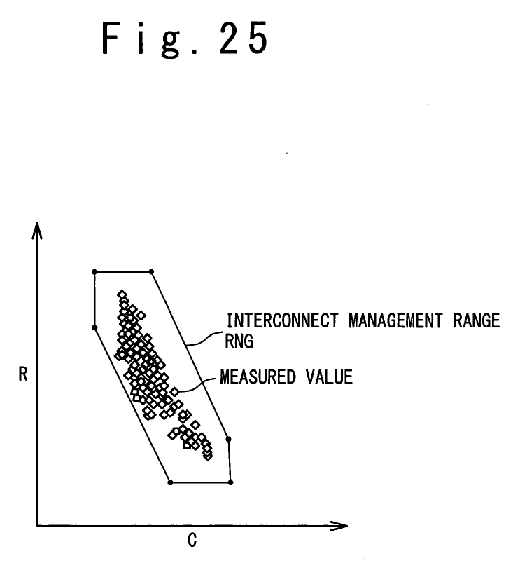

FIG. 25 shows an actual example of the measured values of the interconnect RC and the interconnect management range RNG. In the example shown in FIG. 25, the interconnect management range RNG having the hexagonal shape shown in the foregoing FIG. 12 is used. As can be seen from FIG. 25, the interconnect management range RNG according to the present embodiment well reflects realistic trend of the manufacturing variability of the interconnect RC. By utilizing the interconnect management range RNG, the process management of high precision can be achieved. The interconnect management range RNG according to the present embodiment can be a useful “indicator” on managing the manufacturing variability of the interconnection.

It is apparent that the present invention is not limited to the above embodiments and may be modified and changed without departing from the scope and spirit of the invention.

For example, the present invention can also be applied to a resistor device and a capacitor device that have parasitic resistance and parasitic capacitance (parasitic RC). In this case, manufacturing variability of device parameters contributing to the parasitic RC is considered, instead of the interconnect width and interconnect thickness. The parasitic RC regarding the device is calculated based on a predetermined device model and the process data. At this time, the statistical relaxation is considered. That is to say, the parasitic RC is calculated under a condition that manufacturing variability of the parameters contributing to the parasitic RC is expressed by points on a predetermined circle of equal probability of a joint probability density function. Then, based on a locus of the calculated parasitic RC, a variation range (corresponding to the interconnect management range RNG) of the parasitic RC caused by the manufacturing variability is defined. The variation range is defined tow-dimensionally in a coordinate system where a first axis represents the parasitic resistance and a second axis represents the parasitic capacitance. As in the case of the interconnection, it is possible to manage the manufacturing variability of the device by using the variation range.

What is claimed is:

1. A process management method for managing manufacturing variability of an interconnection included in a semiconductor device, comprising:
calculating interconnect resistance and interconnect capacitance regarding an interconnection included in said semiconductor device, under a condition that manufacturing variability of a width and a thickness of said interconnection is expressed by points on a predetermined circle of equal probability of a joint probability density function; and
defining, based on said calculated interconnect resistance and interconnect capacitance, a variation range of interconnect resistance and interconnect capacitance caused by manufacturing variability,
wherein said variation range is defined two-dimensionally in a coordinate system where a first axis represents interconnect resistance and a second axis represents interconnect capacitance.

2. The process management method according to claim 1, further comprising:
manufacturing said semiconductor device; and
comparing interconnect resistance and interconnect capacitance of a real interconnection included in said manufactured semiconductor device with said variation range in said coordinate system.

3. The process management method according to claim 2, further comprising:
changing a process or a model of said interconnection, based on a result of said comparing.

4. The process management method according to claim 1,
wherein said variation range includes a locus of variation of said calculated interconnect resistance and interconnect capacitance under said condition.

5. The process management method according to claim 4,
wherein Rmax and Rmin are a maximum value and a minimum value of interconnect resistance calculated under said condition, respectively,
Cmax and Cmin are a maximum value and a minimum value of interconnect capacitance calculated under said condition, respectively,
a point defined by said Rmax and said Cmin in said coordinate system is a first point,
a point defined by said Rmin and said Cmax in said coordinate system is a second point, and
said variation range includes said first point and said second point.

6. The process management method according to claim 5,
wherein said variation range has a polygonal shape, and said polygonal shape is included in a rectangular shape having said first point and said second point as diagonal points.

7. The process management method according to claim 6,
wherein said variation range has a hexagonal shape having said first point and said second point as diagonal points.

8. The process management method according to claim 5,
wherein said variation range has an elliptical shape having said first point and said second point as points on a long axis.

9. The process management method according to claim 5,
wherein a correction parameter indicates influence of manufacturing variability of a physical parameter of an interlayer insulating film on interconnect capacitance,
a point obtained by using said correction parameter to correct said first point to be smaller in interconnect capacitance in said coordinate system is a first correction point,
a point obtained by using said correction parameter to correct said second point to be larger in interconnect capacitance in said coordinate system is a second correction point, and
said variation range includes said first correction point and said second correction point.

10. The process management method according to claim 9,
wherein said variation range has a polygonal shape, and said polygonal shape is included in a rectangular shape having said first correction point and said second correction point as diagonal points.

11. The process management method according to claim 10,
wherein said variation range has a hexagonal shape having said first correction point and said second correction point as diagonal points.

12. The process management method according to claim 9,
wherein said variation range has an elliptical shape having said first correction point and said second correction point as points on a long axis.

13. A computer-readable recording medium on which a process management data for managing manufacturing variability of an interconnection included in a semiconductor device is recorded,
said process management data indicating a variation range of interconnect resistance and interconnect capacitance caused by manufacturing variability regarding an interconnection included in said semiconductor device,
wherein said variation range is defined two-dimensionally in a coordinate system where a first axis represents interconnect resistance and a second axis represents interconnect capacitance.

14. The computer-readable recording medium according to claim 13,
wherein said variation range includes a locus of variation of interconnect resistance and interconnect capacitance under a condition that manufacturing variability of a width and a thickness of said interconnection is expressed by points on a predetermined circle of equal probability of a joint probability density function.

15. The computer-readable recording medium according to claim 13,
wherein interconnect resistance and interconnect capacitance of a real interconnection included in said semiconductor device manufactured are compared with said variation range in said coordinate system.

16. A process management method for managing manufacturing variability of a device included in a semiconductor device, comprising:
calculating parasitic resistance and parasitic capacitance regarding a device included in said semiconductor device, under a condition that manufacturing variability of parameters contributing to parasitic resistance and parasitic capacitance of said device is expressed by points on a predetermined circle of equal probability of a joint probability density function; and
defining, based on said calculated parasitic resistance and parasitic capacitance, a variation range of parasitic resistance and parasitic capacitance caused by manufacturing variability,
wherein said variation range is defined two-dimensionally in a coordinate system where a first axis represents parasitic resistance and a second axis represents parasitic capacitance.
